(19) United States
(12) Patent Application Publication
(10) Pub. No.: US 2026/0018473 A1
(43) Pub. Date: Jan. 15, 2026

(54) DETECTION METHOD FOR SEMICONDUCTOR STRUCTURE AND TEST ELEMENT GROUP

(71) Applicant: Winbond Electronics Corp., Taichung City (TW)

(72) Inventor: Chang-Hung LIN, Chiayi City (TW)

(21) Appl. No.: 19/265,157

(22) Filed: Jul. 10, 2025

(30) Foreign Application Priority Data
Jul. 12, 2024 (TW) 113126205

(51) Int. Cl. H01L 21/66; H10B 12/00

(52) U.S. Cl. CPC H01L 22/32; H01L 22/12; H10B 12/053; H10B 12/34; H10B 12/482

(57) ABSTRACT

A detection method for a semiconductor structure, which includes providing a test element group. The test element group includes a plurality of isolation structures and a first word line and a second word line disposed in each of the isolation structures. The first word line and the second word line are on opposite sides of each of the isolation structures. The detection method further includes performing a first etching process on the test element group to remove the upper portion of the isolation structures and expose the top surface of active regions of the test element group. The detection method further includes performing a second etching process on the test element group, and the second etching process is a wet etching process. The detection method further includes performing a defect test on the test element group to determine whether the test element group contains a word line defect.

### CROSS REFERENCE TO RELATED APPLICATIONS

This application claims priority of Taiwan Patent Application No. 113126205 filed on Jul. 12, 2024, the entirety of which is incorporated by reference herein.

### BACKGROUND

### Technical Field

The present disclosure relates to semiconductor technology, and in particular it relates to detection method for semiconductor structure and test element group.

### Description of the Related Art

Using conventional methods of processing semiconductors, unwanted seams may form within the isolation structures while the trench between the active regions is being filled. These seams may adversely retain conductive materials during the subsequent formation of word line (WL) structures, and this may cause short circuits in the subsequently formed conductive components. The existing semiconductor structure detection methods and the corresponding test element groups (TEG) are generally ineffective in detecting the presence of seams within the isolation structures, except through destructive slicing analysis (e.g., transmission electron microscope (TEM) analysis after wafer cross-sectioning). Therefore, there is still a need in the industry to improve the detection methods for semiconductor structures and the associated test element groups, so that the process of manufacturing related memory devices may be optimized based on the detection results, thereby improving the yield of memory devices.

### BRIEF SUMMARY

Embodiments of the present disclosure provide a test element group and a method for detecting whether seams exist within the isolation structures of the test element group.

The present disclosure provides a detection method for a semiconductor structure, including providing a test element group. The test element group includes a plurality of isolation structures and a first word line and a second word line disposed in each of the isolation structures, and the first word line and the second word line are on opposite sides of each of the isolation structures. The detection method further includes performing a first etching process on the test element group to remove an upper portion of the isolation structures and expose the top surface of active regions of the test element group. The detection method further includes performing a second etching process on the test element group, and the second etching process is a wet etching process. The detection method further includes performing a defect test on the test element group to determine whether the test element group contains a word line defect.

The present disclosure provides a test element group, including a substrate having a plurality of active regions and a plurality of isolation structures located between the active regions and a plurality of word lines disposed in the isolation structures. The word lines include a first word line and a second word line at opposite sides of each isolation structure. The test element group further includes a plurality of bit lines disposed over the substrate and in direct contact with the active regions. Each of the bit lines includes a barrier layer, a conductive layer, and a cap layer, and the barrier layer of each of the bit lines is in direct contact with the active regions. The test element group further includes a dielectric layer disposed on the bit lines. The dielectric layer covers top surfaces and sidewalls of the bit lines, and the dielectric layer covers a portion of top surfaces of the active regions and the isolation structures. The test element group further includes a storage node trench penetrating through the dielectric layer to expose the portion of the top surfaces of the active regions.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1, 2, 3, 4, 5, 8, 9, 11, and 12 illustrate cross-sectional views of various formation stages of the test element group according to the embodiments of the present disclosure.

FIG. 6 illustrates a top view of the word line defect according to the embodiments of the present disclosure.

FIGS. 7 and 10 illustrate top views of various formation stages of the test element group according to the embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

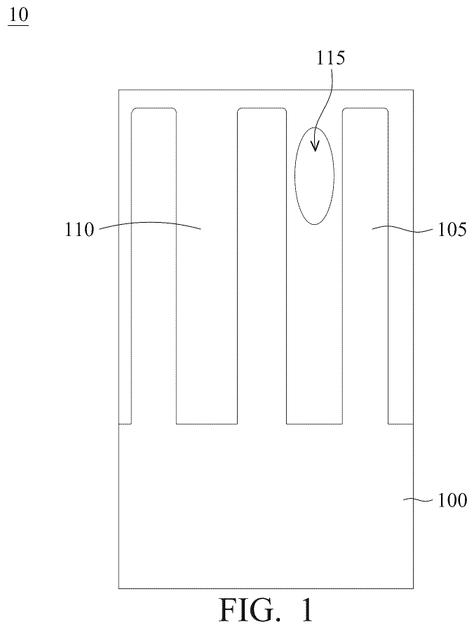

Referring to FIG. 1, a detection method for a semiconductor structure is provided. The detection method includes first providing a test element group 10, and the formation of the test element group 10 includes providing a substrate 100. In some embodiments, the substrate 100 may be an elemental semiconductor substrate, a compound semiconductor substrate, or an alloy semiconductor substrate. In other embodiments, the substrate 100 may be a semiconductor-on-insulator (SOI) substrate. The SOI substrate may include a base substrate, a buried oxide layer disposed on the base substrate, and a semiconductor layer disposed on the buried oxide layer.

The substrate 100 includes a plurality of active regions 105, and further includes a plurality of isolation structures 110 located between the active regions 105. After defining the active regions 105, trenches between the active regions are filled with a dielectric material, followed by a planarization process to form the isolation structures 110 between the active regions 105. As the spacing between the active regions 105 may be scaled down with the development of semiconductor technology, in some embodiments, one of the isolation structures 110 may include a seam 115 due to insufficient gap-filling capability during the formation process of the dielectric material. It should be understood that FIG. 1 illustrates the seam 115 only exemplarily, but the seam 115 may not necessarily exist in the isolation structures 110. In some embodiments, the isolation structures 110 may be formed by chemical vapor deposition (CVD) process or atomic layer deposition (ALD) process. In some embodiments, the material of the isolation structures 110 may include silicon oxide, silicon nitride, high-density plasma (HDP) oxide, low-k dielectric material, spin-on glass, or a combination thereof. In some embodiments, the isolation structures 110 may be shallow trench isolation (STI) structures.

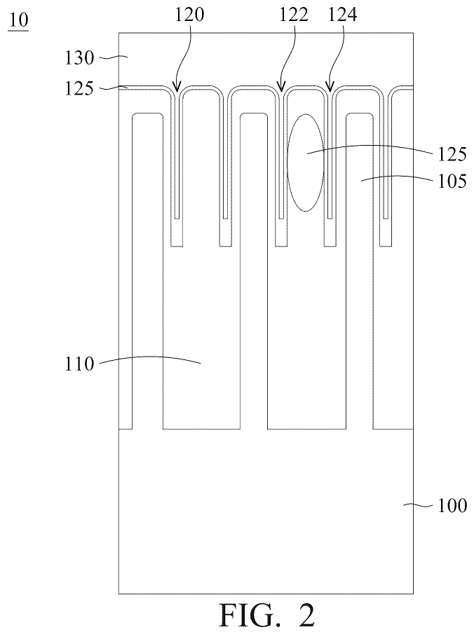

Referring to FIG. 2, an etching process is first performed to form a plurality of openings 120 on opposite sides of each of the isolation structures 110, with the openings 120 adjacent to the active regions 105. In some embodiments, where the seam 115 is present in the isolation structures 110, a first opening 122 and a second opening 124 adjacent to the opening 120 are interconnected by the seam 115. Subsequently, a barrier layer 125 and a conductive layer 130 are sequentially deposited in the openings 120. For example, the barrier layer 125 may be conformally deposited over the substrate 100 and within the openings 120, followed by the formation of the conductive layer 130 to fill the openings 120. It should be noted that, in some embodiments, if the seam 115 is present in the isolation structures 110, the barrier layer 125 may also be formed within the seam 115 through the first opening 122 and the second opening 124. The subsequent word line etching-back process may be unable to remove the barrier layer 125 remaining in the seam 115. In some embodiments, the barrier layer 125 and the conductive layer 130 may be formed by chemical vapor deposition (CVD) process and atomic layer deposition (ALD) process, respectively. In some embodiments, the material of the barrier layer 125 may include titanium (Ti), titanium nitride (TiN), titanium oxide (TiO), tantalum (Ta), tantalum nitride (TaN), tantalum oxide (TaO), or a combination thereof. In some embodiments, the material of the conductive layer 130 may include conductive materials such as doped or undoped polysilicon (poly-Si), metals, or a combination thereof.

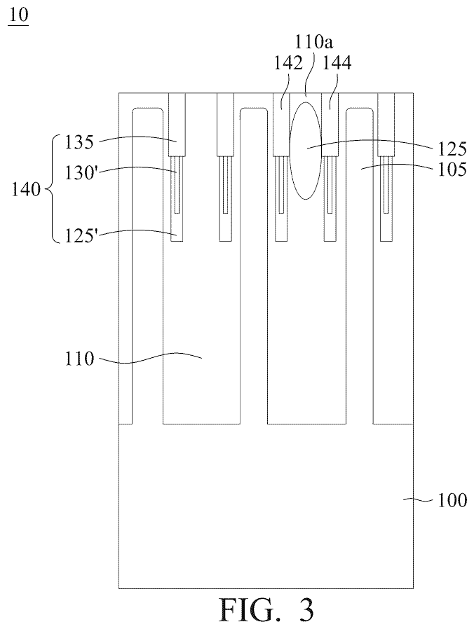

Referring to FIG. 3, after forming the barrier layer 125 and the conductive layer 130, an etching-back process is performed on the barrier layer 125 and the conductive layer 130 to form a barrier layer 125′ and a conductive layer 130′. More specifically, make the top surface of the remaining conductive layer 130′ in the opening 120 lower than the top surface of the active regions 105. Subsequently, a cap layer 135 is formed over the conductive layer 130′ and fills the remaining portion of the opening 120, thereby forming a plurality of word lines 140. The word lines 140 are formed in the openings 120 and include, from bottom to top, the barrier layer 125′, the conductive layer 130′, and the cap layer 135. In some embodiments, the etching-back process may include a dry etching process.

The word lines 140 include a first word line 142 and a second word line 144, which are respectively formed in the first opening 122 and the second opening 124. In some embodiments, where the seam 115 is present in the isolation structures 110, the first word line 142 and the second word line 144 are located on opposite sides of the seam 115, and the first word line 142 is connected to the second word line 144 by the seam 115. In other words, if the seam 115 exists within the isolation structures 110, the barrier layer 125 unintentionally formed in the seam 115 may cause a short circuit between the first word line 142 and the second word line 144.

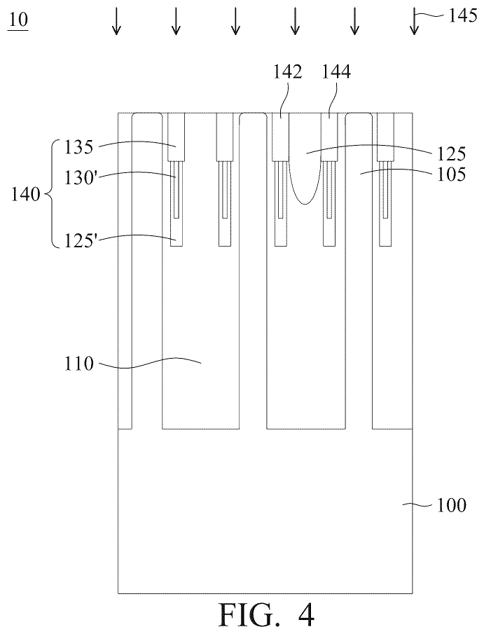

Referring to FIG. 3 in conjunction with FIG. 4, after the formation of the word lines 140, a first etching process 145 may be performed on the test element group 10 to remove an upper portion 110a of the isolation structures 110 (as shown in the resulting structure in FIG. 4), thereby preparing the structure for a subsequent defect test. In a conventional memory device fabrication process, deposition, photolithography, and etching processes are subsequently performed to form the bit line contacts. The first etching process 145 may be regarded as the pre-bit-line-contact etching process, that is, the first etching process 145 etches the upper portion 110a of the isolation structures 110 and exposes the active regions 105. In addition, the first etching process 145 also etches the upper portion 110a of the isolation structures 110 and exposes the barrier layer 125 that was formed in the seam 115. In some embodiments, the first etching process 145 may include a dry etching process.

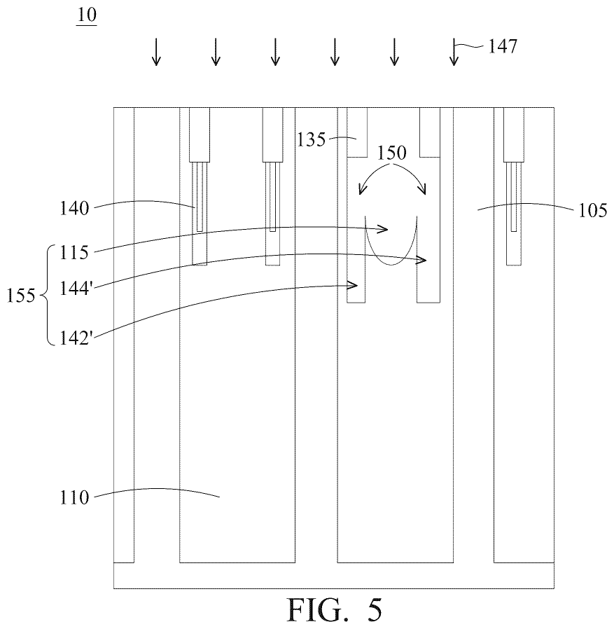

Referring to FIG. 5, after the first etching process 145 is performed, a second etching process 147 is subsequently performed on the test element group 10. In some embodiments, if the seam 115 is present in the isolation structures 110, the first etching process 145 first exposes the barrier layer 125 formed in the seam 115. Subsequently, the second etching process 147 etches through the entire seam 115 as well as the entire first word line 142 and the entire second word line 144. More specifically, in some embodiments, the second etching process 147 is a wet etching process. After the first etching process 145 exposes the barrier layer 125 within the seam 115, the chemical used in the second etching process 147 flows into the seam 115 and etches the remaining barrier layer 125 therein, along with the barrier layers 125′ and the conductive layers 130′ of the first word line 142 and the second word line 144 connected to the seam 115 (for example, the chemical flows along a direction 150). In some embodiments, the chemical may include a mixture of H₂SO₄ and H₂O₂, or a mixture of NH₄OH and H₂O₂.

After the second etching process 147 is performed, the seam 115 and the void 142′ and the void 144′ of the interconnected first word line 142 and the second word line 144 collectively form a word line defect 155. The second etching process 147 removes the corresponding barrier layers 125′ and the conductive layers 130′ of the first word line 142 and the second word line 144, while leaving the corresponding cap layers 135. In other words, after the second etching process 147, the first word line 142 and the second word line 144 no longer include the barrier layers 125′ and the conductive layers 130′, but instead each includes the void 142′ and the void 144′, respectively. After the formation of the word line defect 155, the test element group 10 has completed the preprocessing for defect testing and may subsequently undergo a defect test to detect and determine whether the test element group 10 contains the word line defect 155.

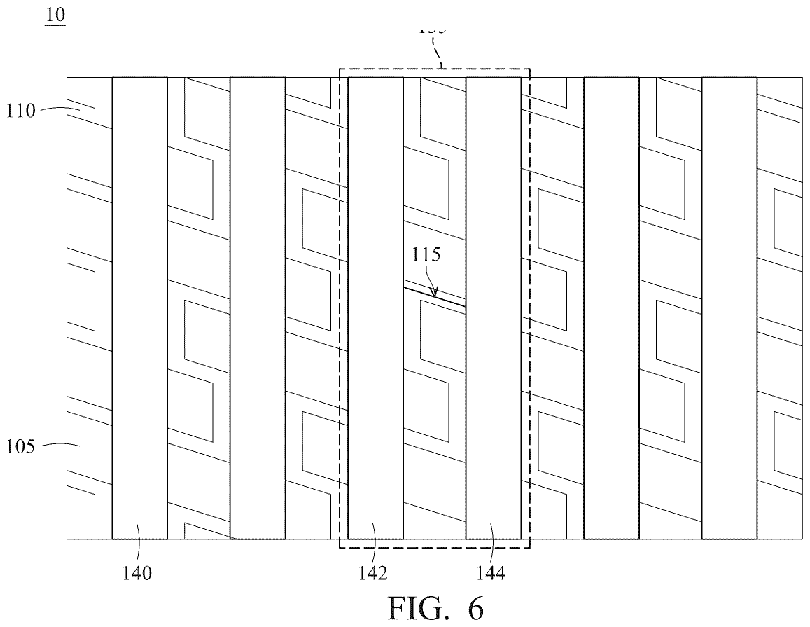

FIG. 6 illustrates a top view of the test element group 10 after the formation of the word line defect 155 in the presence of the seam 115, according to the embodiment of the present disclosure. Since the seam 115, the first word line 142, and the second word line 144 are all etched (with only the cap layer 135 remaining), the associated defect inspection equipment may easily detect and determine whether the test element group 10 contains the word line defect 155. For example, in the top view, in the presence of a seam 115, the word line defect 155 lacks the conductive layer 130′, resulting in a significant color difference between the word line defect 155 and the surrounding normal word lines 140, thereby reducing the difficulty of detection and identification. More specifically, after performing the defect test, if the word line defect 155 is detected in the test element group 10, there must be a seam 115 within the isolation structures 110 at the corresponding position of the word line defect 155. It should be noted that although the first word line 142 is not actually formed in conjunction with the second word line 144, but in some embodiments, the entire word line defect 155 is a rectangle shape with a significant color difference from the surrounding standard (or normal) word lines 140 in the top-view.

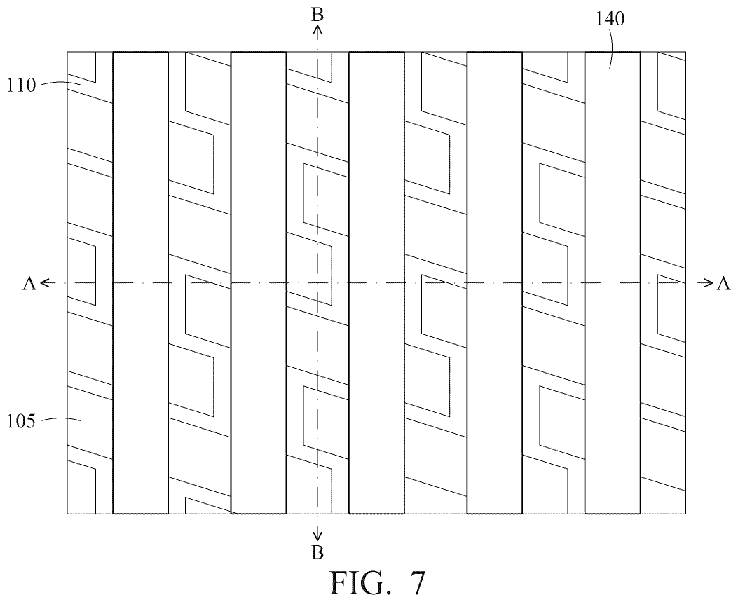

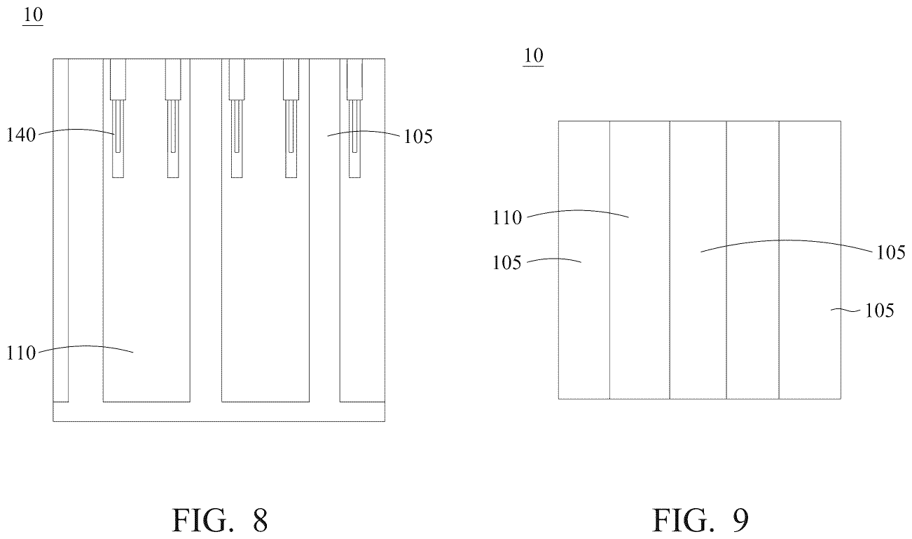

Referring to FIG. 7 in conjunction with FIGS. 8 and 9, FIG. 7 illustrates a top view of the test element group 10 according to the embodiment of the present disclosure. FIGS. 8 and 9 illustrate cross-sectional views of the test element group 10 along the line A-A and the line B-B of FIG. 7, respectively, according to the embodiments of the present disclosure. More specifically, FIGS. 1 to 5 may also correspond to the cross-sectional view along the line A-A in FIG. 7. In FIG. 8, since no seam 115 exists in the isolation structures 110, the first etching process 145 and the second etching process 147 do not form a word line defect 155 in the isolation structures 110, and thus the subsequent defect test does not detect the presence of the word line defect 155. In contrast, in FIG. 9, because no bit line contact is formed in the test element group 10, no corresponding structure is present over the active regions 105.

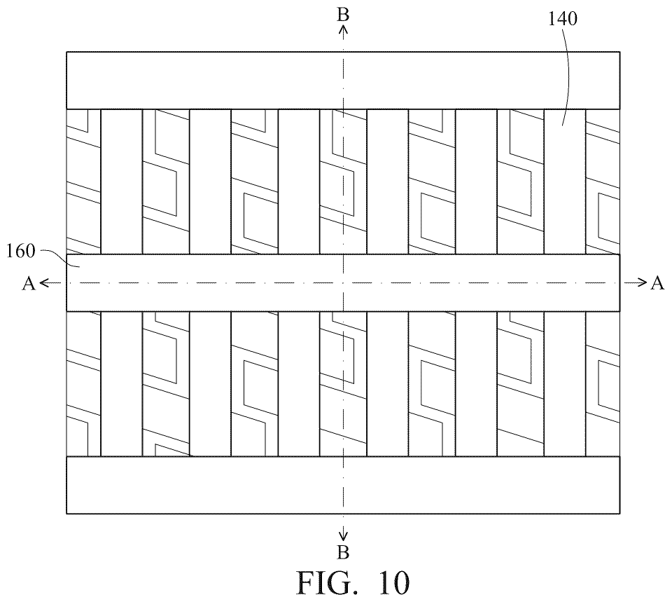

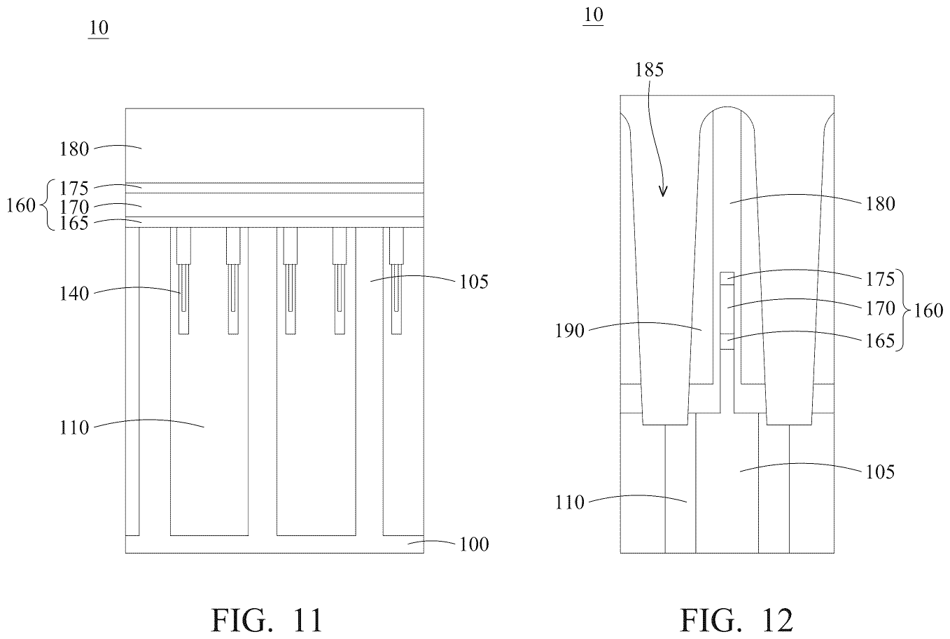

Referring to FIG. 10 in conjunction with FIGS. 11 and 12, FIG. 10 illustrates a top-view of the test element group 10 according to the embodiment of the present disclosure. FIGS. 11 and 12 illustrate cross-sectional views of the test element group 10 after performing the defect test and subsequent processes along the line A-A and the line B-B of FIG. 10, respectively. After performing the defect test, the test element group 10 may continue the process of the memory device. For example, a bit line 160 may be formed on the substrate 100 of the test element group 10. As shown in FIGS. 11 and 12, in order to effectively detect the seam 115 in the isolation structures 110, no bit line contact is formed on the active regions 105, such that the bit line 160 (i.e., the barrier layer 165) directly contacts the active regions 105. In some embodiments, the bit line 160 includes a barrier layer 165, a conductive layer 170, and a cap layer 175. After forming the bit line 160, a dielectric layer 180 is formed to cover and protect the bit line 160. Referring to FIG. 12, as described above, the bit line 160 (i.e., the barrier layer 165) directly contacts the active regions 105, and the dielectric layer 180 covers the entire sidewalls and top surface of the bit line 160, and covers a portion of the top surfaces of the active regions 105 and the isolation structures 110. In addition, after forming the dielectric layer 180, a dielectric liner 190 is further formed on the substrate 100 and covers the sidewalls of the dielectric layer 180. The dielectric liner 190 further isolates the bit line 160 from a subsequently formed storage node contact 195. The test element group 10 also includes a storage node trench 185, which is formed by performing photolithography and etching processes on the test element group 10. The storage node trench 185 penetrates the dielectric layer 180 and the dielectric liner 190 and exposes a portion of the top surfaces of the active regions 105. The storage node trench 185 may be subsequently used to form the storage node contact 195, which is filled into the storage node trench 185. In some embodiments, the barrier layer 165, the conductive layer 170, the cap layer 175, and the dielectric liner 190 may be respectively formed by chemical vapor deposition (CVD) process or atomic layer deposition (ALD) process. In some embodiments, the material of the barrier layer 165 may include titanium (Ti), titanium nitride (TiN), titanium oxide (TiO), tantalum (Ta), tantalum nitride (TaN), tantalum oxide (TaO), or a combination thereof. In some embodiments, materials of the conductive layer 170 and the storage node contact 195 may include conductive material, such as doped or undoped polysilicon, metal, or a combination thereof. In some embodiments, the material of the cap layer 175 may include silicon oxide (SiO), silicon nitride (SiN), silicon oxynitride (SiON), silicon carbide (SiC), silicon carbon nitride (SiCN), or a combination thereof. In some embodiments, the material of the dielectric liner 190 may be oxide material.

In summary, compared to conventional methods for detecting seams within the isolation structures of the test element group, the detection method provided in the embodiments of the present disclosure enables the removal of the seam and the conductive materials of the two word lines connected to the seam through etching processes when the seam is present in the isolation structures, thereby forming a word line defect that is easier to detect. In other words, the embodiments of the present disclosure utilize two etching processes to convert an originally small-sized seam into a larger-sized word line defect, which allows effective detection of the seam-related defect. Based on the detection result, relevant process parameters may be fine-tuned to improve the yield of memory devices. Furthermore, in order to effectively detect the seam, the embodiments of the present disclosure may be easily integrated into existing semiconductor manufacturing by omitting the formation of the bit line contact in the test element group, and by using the subsequent etching process prior to the formation of the bit line contact as the aforementioned etching process for the removal of the seam as well as the etching process of the conductor material in the two word lines connected to the seam. It should be understood that not all advantages have been necessarily discussed here, and not all embodiments require specific advantages, and other embodiments may offer different advantages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A detection method for a semiconductor structure, comprising:
providing a test element group, wherein the test element group comprises a plurality of isolation structures and a first word line and a second word line disposed in each of the isolation structures, and wherein the first word line and the second word line are on opposite sides of each of the isolation structures;
performing a first etching process on the test element group to remove an upper portion of the isolation structures and expose top surfaces of a plurality of active regions of the test element group;
performing a second etching process on the test element group, wherein the second etching process is a wet etching process; and
performing a defect test on the test element group to determine whether the test element group contains a word line defect.

2. The detection method as claimed in claim 1, wherein providing the test element group further comprises:
performing an etching process on the isolation structures to form a first opening and a second opening on the opposite sides of each of the isolation structures;
sequentially depositing a barrier layer and a conductive layer in the first opening and the second opening;
performing an etching-back process on the barrier layer and the conductive layer; and
forming a cap layer on the conductive layer and filling the cap layer into remaining portions of the first opening and the second opening to form the first word line and the second word line.

3. The detection method as claimed in claim 1, wherein after performing the defect test, if the test element group comprises a word line defect, one of the isolation structures has a seam corresponding to the word line defect, and the first word line is connected to the second word line by the seam.

4. The detection method as claimed in claim 3, wherein the first word line and the second word line each comprise a barrier layer and a conductive layer, and wherein the second etching process etches the barrier layer and the conductive layer of the first word line and the second word line through the seam to form the word line defect.

5. The detection method as claimed in claim 3, wherein a barrier layer remains in the seam, and wherein performing the first etching process further comprises exposing the barrier layer in the seam.

6. The detection method as claimed in claim 1, wherein the word line defect is a rectangle shape in a top view.

7. The detection method as claimed in claim 1, wherein during the defect test, the word line defect has a significant color difference from a standard word line of the test element group.

8. The detection method as claimed in claim 1, wherein the isolation structures are disposed between the active regions of the test element group, and after performing the defect test, the test element group further comprises:
forming a plurality of bit lines on the active regions, wherein the bit lines are in direct contact with the active regions.

9. The detection method as claimed in claim 1, wherein the second etching process uses a chemical to etch the test element group, and wherein the chemical comprises a mixture of H₂SO₄ and H₂O₂, or a mixture of NH₄OH and H₂O₂.

10. A test element group, comprising:
a substrate having a plurality of active regions and a plurality of isolation structures located between the active regions;
a plurality of word lines disposed in the isolation structures, wherein the word lines comprise a first word line and a second word line at opposite sides of each of the isolation structures;
a plurality of bit lines disposed over the substrate and in direct contact with the active regions, wherein each of the bit lines comprises a barrier layer, a conductive layer, and a cap layer, and the barrier layer of each of the bit lines is in direct contact with the active regions;
a dielectric layer disposed on the bit lines, wherein the dielectric layer covers top surfaces and sidewalls of the bit lines, and the dielectric layer covers a portion of top surfaces of the active regions and the isolation structures; and
a storage node trench penetrating through the dielectric layer to expose the portion of the top surfaces of the active regions.

11. The test element group as claimed in claim 10, wherein if the test element group comprises a word line defect after performing a defect test, one of the isolation structures has a seam corresponding to the word line defect.

12. The test element group as claimed in claim 11, wherein the seam and the first word line and the second word line connected by the seam collectively form the word line defect.

13. The test element group as claimed in claim 10, wherein the word line defect is a rectangle shape in a top view.

14. The test element group as claimed in claim 10, wherein the substrate and the word lines are processed by an etching process to form the word line defect.

15. The test element group as claimed in claim 10, further comprising a storage node contact filled in the storage node trench, wherein the storage node contact is separated from each of the bit lines by the dielectric layer.

16. The test element group as claimed in claim 15, wherein a material of the storage node contact comprises doped or undoped polycrystalline silicon, metal, or a combination thereof.

17. The test element group as claimed in claim 10, further comprising a dielectric liner disposed on the substrate and covering sidewalls of the dielectric layer.

18. The test element group as claimed in claim 10, wherein a material of the barrier layer comprises titanium (Ti), titanium nitride (TiN), titanium oxide (TiO), tantalum (Ta), tantalum nitride (TaN), tantalum oxide (TaO), or a combination thereof.

19. The test element group as claimed in claim 10, wherein a material of the conductive layer comprises doped or undoped polycrystalline silicon, metal, or a combination thereof.

20. The test element group as claimed in claim 10, wherein a material of the cap layer comprises silicon oxide (SiO), silicon nitride (SiN), silicon oxynitride (SiON), silicon carbide (SiC), silicon carbon nitride (SiCN), or a combination thereof.
